(19) United States
(12) Patent Application Publication
(10) Pub. No.: US 2026/0140437 A1
(43) Pub. Date: May 21, 2026

(54) PELLICLE AND METHOD FOR EXTREME ULTRAVIOLET LITHOGRAPHY

(71) Applicant: Taiwan Semiconductor Manufacturing Company, Ltd., Hsinchu (TW)

(72) Inventors: Pei-Hsun TSAI, Hsinchu (TW); Yun-Yue LIN, Hsinchu (TW)

(73) Assignee: Taiwan Semiconductor Manufacturing Company, Ltd., Hsinchu (TW)

(21) Appl. No.: 18/955,132

(22) Filed: Nov. 21, 2024

(51) Int. Cl. G03F 1/64; G03F 7/00

(52) U.S. Cl. CPC G03F 1/64; G03F 7/70983

(57) ABSTRACT

A pellicle for protecting a photomask from contaminant particles during photolithography is provided. The pellicle includes a pellicle membrane having a network of boron carbonitride (BCN) nanostructures. The pellicle membrane is attached to a pellicle frame that is mounted to a photomask to be used during photolithography operations.

### BACKGROUND

In the semiconductor integrated circuit (IC) industry, technological advances in materials and design have produced ICs where each generation has smaller and more complex circuits than the previous generation. The functional density (i.e., the number of interconnected devices per chip area) has generally increased while geometry size (i.e., the smallest component (or line) that can be created using a fabrication process) has decreased. This scaling-down process generally provides benefits by increasing production efficiency and lowering associated costs but also has increased the complexity of IC processing and manufacturing.

During a photolithography process, a patterned resist layer is formed for various patterning processes, such as etching or ion implantation. The minimum feature size that may be patterned by way of such a photolithography process is limited by the wavelength of the projected radiation source. Existing photolithography equipment uses deep ultraviolet (DUV) light including a krypton fluoride laser (KrF laser) of 248 nanometers and an argon fluoride laser (ArF laser) of 193 nanometers, as well as extreme ultraviolet (EUV) light of a wavelength of 13.5 nanometers.

In the photolithography process, a photomask is used. The photomask includes a substrate and a patterned layer that defines an IC to be transferred to a semiconductor substrate during the photolithography process. The photomask is typically included with a pellicle. The pellicle includes a transparent thin membrane and a pellicle frame, where the membrane is mounted over the pellicle frame. The pellicle protects the photomask from fallen particles and keeps the particles out of focus so that they do not produce a patterned image, which may cause defects when the photomask is being used. Existing pellicles are exposed to harsh photolithography conditions and the optical performance of the pellicle may be subject to degradation due to exposure to temperature and light. There remains room for improved pellicle materials with EUV exposure stability and optimized mechanical and optical properties.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of a photolithography system constructed in accordance with some embodiments of the present disclosure.

FIG. 2 is a cross-sectional view of a photomask-pellicle assembly, according to some embodiments of the present disclosure.

FIG. 3 is a cross-sectional view of another photomask-pellicle assembly with a protective coating, according to other embodiments of the present disclosure.

FIG. 4 is an exploded view of a pellicle, according to some embodiments of the present disclosure.

FIG. 5 is a flow diagram illustrating a method of forming a photomask-pellicle assembly, according to at least one embodiment of the present disclosure.

FIG. 6 illustrates a flowchart of a method of manufacturing a semiconductor device, according to at least one embodiment of the present disclosure.

FIG. 7 illustrates an example of a BCN nanostructure, according to at least one embodiment of the present disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in between the described operations, and the order of operations may be changed. In the present disclosure, the phrase “at least one of A, B and C” means either one of A, B, C, A+B, A+C, B+C or A+B+C, and does not mean one from A, one from B, and one from C, unless otherwise explained.

In one example, the present disclosure provides a durable, high-transmission pellicle used with EUV lithography equipment. In certain embodiments, an EUV lithography scanner uses EUV radiation to project a pattern formed in a photomask onto a silicon wafer and the pattern may be etched into the wafer. In some examples, the pellicle is used to protect the photomask from contamination. For instance, particles may fall onto the surface of the photomask. When the EUV lithography scanner subsequently prints or transfers the photomask pattern onto the wafer, the particles may also print or transfer onto the wafer, resulting in defects in the pattern. However, a properly positioned pellicle can prevent the particles from falling onto the photomask.

Although pellicles can reduce photomask contamination, pellicles can also reduce the amount of EUV radiation that reaches the photomask. For instance, if the membrane of the pellicle is too thick, the membrane may absorb much of the EUV radiation before the EUV radiation can reach the photomask, which may in turn reduce the throughput of the EUV lithography scanner. Moreover, existing materials of the pellicle membrane may be prone to mechanical deformation under the typical processing conditions of an EUV or DUV lithography system. For example, an EUV lithography system may operate at an exposure energy of 400 to 600 Watts. Under such conditions, the temperature of the pellicle membrane may reach 600 to 800 degrees Celsius, which is well over the melting point of many materials. As such, conventional pellicles may need to be replaced relatively frequently.

Examples of the present disclosure provide a durable, high-transmission pellicle that is resistant to temperature-induced deformation and that transmits a high percentage (e.g., 94% or greater) of radiation onto the photomask. In certain embodiments, the EUV reflectivity of the pellicle is between 0.01 to 0.05%, and the DUV reflectivity of the pellicle is reduced to less than 24%. In one example, the pellicle includes a membrane comprising a ternary compound including a network of boron carbonitride (BCN) nanostructures. In other examples, the network of BCN nanostructures includes optimized dopant(s) at a concentration that extends EUV transmission and exposure lifespan of the pellicle. In some embodiments, the network of BCN nanostructures is doped with one or more dopants selected from molybdenum (Mo), oxygen (O), niobium (Nb), silicon (Si), or yttrium (Y). In certain embodiments, the dopant acts as a grain growth controller that assists in exposure stability.

In other embodiments, one or more protective layers are disposed on a surface(s) of the pellicle membrane, and the material of the protective layer is selected from one or more of a metal, metal oxide, carbide, or nitride. In other embodiments, an additional element of Si, B, C, N, P, or O is added to the BCN nanostructure to further control grain growth and increase exposure stability. In certain embodiments, when an additional element of Si, B, C, N, P, or O is added to the BCN nanostructure, a mixing interface is formed between the BCN nanostructure and the protective layer.

In some embodiments of the present disclosure, the pellicle membrane comprises a network of BCN nanostructures selected from nanotubes, nanowires, nanofibers, nanosheets, or nanocages. The pellicle membrane is mechanically robust and is DUV and EUV durable while allowing for improved transmission of radiation. In some embodiments, the BCN nanostructures are amorphous, while in other embodiments the BCN nanostructures are crystalline.

Additional features can be added to the pellicle disclosed herein. Some of the features described below can also be replaced or eliminated for different examples. Although some examples disclosed below discuss operations that are performed in a particular order, these operations may be performed in other orders as well without departing from the scope of the present disclosure. Throughout the various views and illustrative embodiments, like reference numbers are used to designate like elements.

Moreover, in other examples, the pellicle and methods disclosed herein may be deployed in a plurality of applications, including the fabrication of transistors. For instance, certain examples of the present disclosure may be well suited for patterning features including lines, trenches, or vias to produce a relatively close spacing between features.

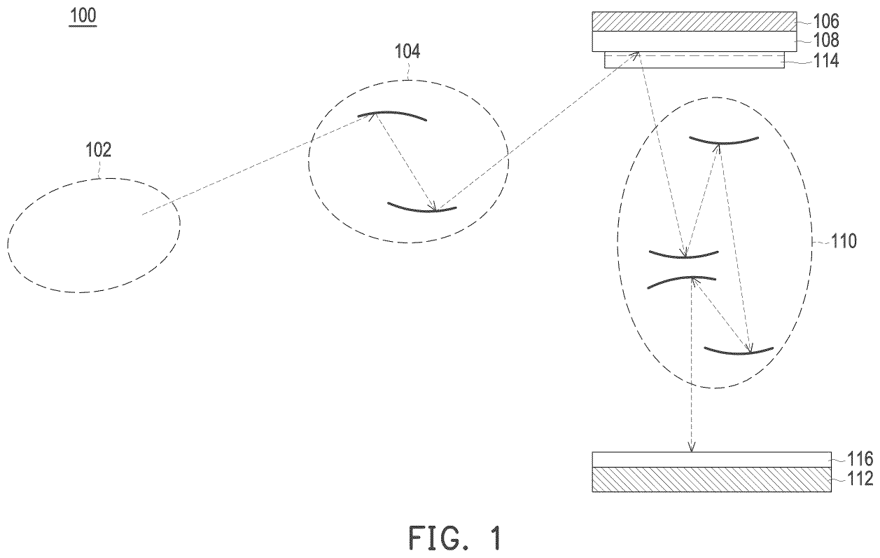

FIG. 1 is a simplified schematic diagram of a photolithography system 100 according to examples of the present disclosure. The photolithography system 100 may also be referred to herein as a scanner that is operable to perform photolithography exposing processes with respective radiation sources and exposure modes.

In one example, the photolithography system 100 includes an exposure light source 102, an illuminator 104, a mask stage 106, a photomask 108, a projection optics module 110, and a substrate stage 112. In some examples, the photolithography system 100 includes additional components that are not illustrated in FIG. 1. In further examples, one or more of the light source 102, the illuminator 104, the mask stage 106, the photomask 108, the projection optics module 110, and the substrate stage 112 are omitted from the photolithography system 100 or are integrated into combined components.

In certain embodiments, the light source 102 is configured to emit radiation having wavelengths in the range of approximately 1 nanometer to 250 nanometers. In one particular example, the light source 102 generates EUV light with a wavelength centered at approximately 13.5 nanometers; accordingly, in some examples, the light source 102 may also be referred to as an EUV light source. However, it will be appreciated that the light source 102 is not limited to emitting EUV light. For instance, the light source 102 is utilized to perform any high-intensity photon emission from an excited target material.

In some examples (e.g., where the photolithography system 100 is a UV lithography system), the illuminator 104 includes various refractive optical components, such as a single lens or a lens system comprising multiple lenses (zone plates). In another example (e.g., where the photolithography system 100 is an EUV lithography system), the illuminator 104 comprises various reflective optical components, such as a single mirror or a mirror system comprising multiple mirrors. The illuminator 104 may direct light from the exposure light source 102 onto the mask stage 106, and more particularly onto the photomask 108 that is secured onto the mask stage 106. In an example where the light source 102 generates light in the EUV wavelength range, the illuminator 104 comprises reflective optics.

In some embodiments, the mask stage 106 is configured to secure the photomask 108. In some examples, the mask stage 106 includes an electrostatic chuck (e-chuck) to secure the photomask 108. Because gas molecules absorb EUV light, the photolithography system 100 for EUV lithography patterning is maintained in a vacuum environment to minimize EUV intensity loss. Herein, the terms photomask, mask, and reticle may be used interchangeably. In one example, the photomask 108 is a reflective mask.

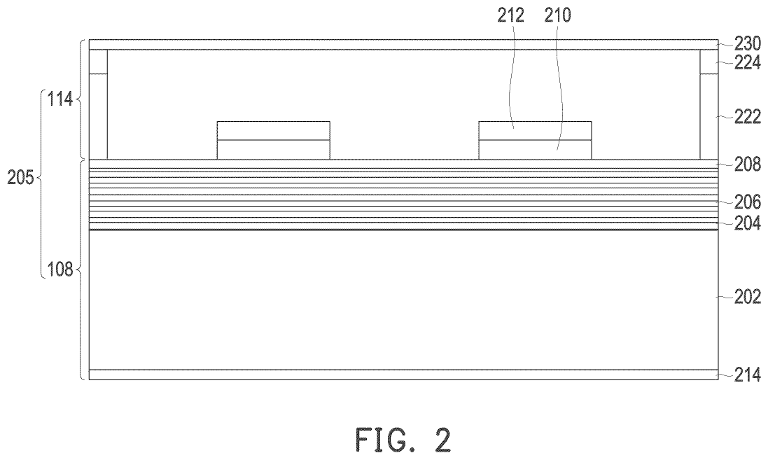

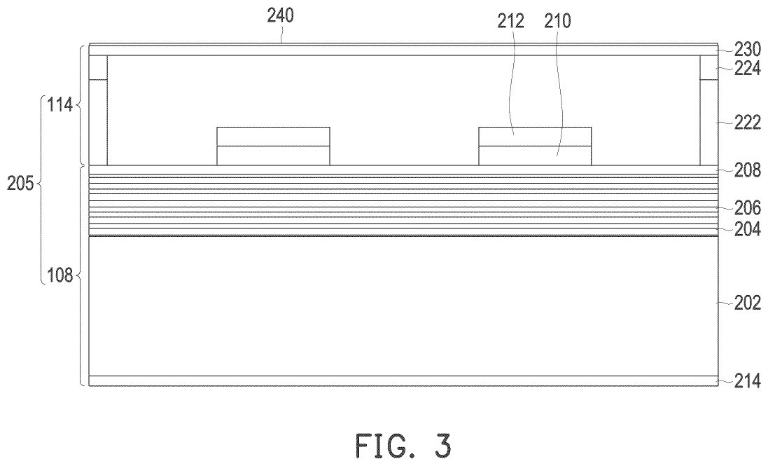

In some embodiments of the present disclosure, a pellicle 114 is positioned over the photomask 108, e.g., between the photomask 108 and the substrate stage 112. The pellicle 114 may protect the photomask 108 from particles and may keep the particles out of focus so that the particles do not produce an image (which may cause defects on a semiconductor wafer 116 during the photolithography process). In certain embodiments of the present disclosure, a BCN pellicle membrane (FIG. 2) or a BCN pellicle membrane with a protective layer (FIG. 3) is used.

In some embodiments, the projection optics module 110 is configured for imaging the pattern of the photomask 108 onto a semiconductor wafer 116 secured on the substrate stage 112. In one example, the projection optics module 110 comprises refractive optics (such as for a UV lithography system). In another example, the projection optics module 110 comprises reflective optics (such as for an EUV lithography system). The light directed from the photomask 108, carrying the image of the pattern defined on the photomask 108, is collected by the projection optics module 110. The illuminator 104 and the projection optics module 110 may be collectively referred to as an optical module of the photolithography system 100.

In some examples, the semiconductor wafer 116 may be a bulk semiconductor wafer. In some embodiments, the semiconductor wafer 116 includes a silicon wafer. In other examples, the semiconductor wafer 116 includes another elementary semiconductor material, such as germanium. In some examples, the semiconductor wafer 116 includes a compound semiconductor. In other examples, the compound semiconductor includes gallium arsenide, silicon carbide, indium arsenide, indium phosphide, another suitable material, or a combination thereof. In yet other examples, the semiconductor wafer 116 includes a silicon-on-insulator (SOI) substrate. In certain embodiments, the SOI substrate is fabricated using a separation by implantation of oxygen (SIMOX) process, a wafer bonding process, another applicable process, or a combination thereof. In some examples, the semiconductor wafer 116 comprises an undoped substrate. However, in other examples, the semiconductor substrate 116 comprises a doped substrate, such as a p-type substrate or an n-type substrate.

In some examples, the semiconductor wafer 116 includes various doped regions (not shown) depending on the design requirements of the semiconductor device structure. The doped regions may include, for example, p-type wells and/or n-type wells. In some examples, the doped regions are doped with p-type dopants such as boron or boron fluoride. In other examples, the doped regions are doped with n-type dopants such as phosphorus or arsenic. In some examples, some of the doped regions are p-doped and other doped regions are n-doped.

In some embodiments, an interconnection structure is formed over the semiconductor wafer 116. The interconnection structure includes multiple interlayer dielectric layers, including dielectric layers. In some embodiments, the interconnection structure includes multiple conductive features formed in the interlayer dielectric layers. In certain embodiments, the conductive features include conductive lines, conductive vias, and/or conductive contacts.

In some examples, various device elements are formed in the semiconductor wafer 116. Examples of the various device elements include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. In some embodiments, various processes are used to form the various device elements, including deposition, etching, implantation, photolithography, annealing, and/or other applicable processes.

In some embodiments, the device elements are interconnected through the interconnection structure over the semiconductor wafer 116 to form IC devices. In some embodiments, the IC devices include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some examples, the semiconductor wafer 116 is coated with a resist layer that is sensitive to actinic radiation, such as DUV or EUV light. In other embodiments, the various components including those described above are integrated and are operable to perform lithography-exposing processes.

FIG. 2 illustrates a cross-sectional view of a photomask-pellicle assembly 205 used in photolithography, according to some embodiments. The photomask-pellicle assembly 205 includes a photomask 108 and a pellicle 114. The illustrative photomask 108 is a reflective mask of a type used in EUV lithography and includes a substrate 202, alternating reflective layers 204, spacing layers 206, a capping layer 208, an EUV absorbing layer 210 that is patterned to define a pattern region or surface of the photomask, an anti-reflective coating (ARC) 212, and a conductive backside layer 214. The illustrative photomask 108 is merely a non-limiting example. The pellicle 114 as disclosed herein is used with substantially any type of reflective or transmission reticle. As another example (not shown), the photomask 108 is a transmission reticle, in which case the substrate is transmissive for light at the wavelength at which the photolithography is performed. In general, the reflective or transmissive reticle includes a substrate (e.g., substrate 202) and a mask pattern (e.g., absorbing layer 210) disposed on the substrate 202. As illustrated in the embodiment of FIG. 2, the pellicle 114 includes a mounting frame 222, an adhesive layer 224, and a pellicle membrane 230. In some embodiments, the photomask-pellicle assembly 205 is intended for use with EUV light wavelengths, for example from about 10 nm to about 124 nm, including about 13.5 nm.

In some embodiments, the substrate 202 is made from a low thermal expansion material (LTEM), such as quartz or titania silicate glasses. In some examples, the substrate 202 comprises a transparent substrate, such as fused silica that is substantially free of defects, borosilicate glass, soda-lime glass, calcium fluoride, low thermal expansion material, ultra-low thermal expansion material, or other applicable materials. The substate 202 helps reduce or prevent warping of the reticle due to the absorption of energy and consequent heating. The reflective layers 204 and the spacing layers 206 cooperate to form a Bragg reflector for reflecting EUV light. In some embodiments, the reflective layers 204 include molybdenum (Mo) and the spacing layers 206 comprise silicon (Si). The capping layer 208 is used to protect the reflector formed from the reflective layers 204 and the spacing layers 206, for example from oxidation and etching. In some embodiments, the capping layer 208 comprises ruthenium (Ru). The EUV absorbing layer 210 absorbs EUV wavelengths and is patterned with the desired pattern. In some embodiments, the EUV absorbing layer 210 comprises tantalum boron nitride. The anti-reflective coating (ARC) 212 further reduces reflection from the EUV absorbing layer. In some embodiments, the anti-reflective coating 212 comprises oxidized tantalum boron nitride. The conductive backside layer 214 permits the mounting of the illustrative reticle on an electrostatic chuck and temperature regulation of the mounted substrate 202. In some embodiments, the conductive backside layer 214 comprises chrome nitride.

Pellicle 114 includes the mounting frame 222 that supports the pellicle membrane 230 at a height sufficient to take the pellicle membrane 230 outside the focal plane of the photolithography, e.g., several millimeters (mm) over the photomask 108 in some non-limiting illustrative embodiments. In some embodiments, the mounting frame 222 itself is made from suitable materials, such as anodized aluminum, stainless steel, plastic, silicon (Si), titanium, silicon dioxide, aluminum oxide (Al₂O₃), or titanium dioxide (TiO₂). In some examples, suitable processes for forming the mounting frame 222 include machining processes, sintering processes, photochemical etching processes, other applicable processes, or a combination thereof.

In other embodiments, vent holes (not shown) are provided in the mounting frame 222 for equalizing pressure on both sides of the pellicle membrane 230. In some examples, the vent structure comprises one or more apertures formed in a side portion of the mounting frame 222. In some embodiments, the apertures take any shape, including circular apertures, rectangular apertures, slit-shaped apertures, other shapes, or any combination thereof. In some embodiments, the apertures allow for a flow of the ambient atmosphere in the photolithography system through a portion of the photomask-pellicle assembly 205. In some examples, the apertures may include filters to minimize the passage of outside particles through the vent holes. In some examples, the vent holes may be formed using a photochemical etching process, another applicable process, or a combination thereof.

In some embodiments, the adhesive layer 224 is used to secure the pellicle membrane 230 to the mounting frame 222. Suitable adhesives may include silicone, epoxy, thermoplastic elastomer rubber, acrylic polymer, acrylic copolymer, or combinations thereof. In some embodiments, the adhesive layer 224 has a crystalline and/or amorphous structure. In some embodiments, the adhesive layer 224 has a glass transition temperature (Tg) that is above a maximum operating temperature of the photolithography system, to prevent the adhesive from exceeding the Tg during the operation of the system.

In some examples, the adhesive layer 224 includes heat-dissipating fillers. The heat-dissipating fillers may include, for example, aluminum nitride, boron nitride, aluminum oxide, magnesium oxide, silicon oxide, graphite, metal powder, ceramic powder, another suitable material, or a combination thereof. In some examples, the EUV lithography process may involve an EUV light beam that penetrates the pellicle membrane 230, causing the temperature of the pellicle membrane 230 to increase. The heat-dissipating fillers may help to dissipate the heat of the pellicle membrane 230 through the adhesive layer 224, to the mounting frame 222, to the photomask 108, and to the EUV lithography scanner. Thus, in some embodiments, the maximum temperature of the pellicle membrane 230 is reduced during EUV lithography processing using pellicles according to embodiments of the disclosure, thereby reducing the likelihood of the pellicle membrane 230 rupturing.

In some examples, a surface treatment is performed on the mounting frame 222 to enhance the adhesion of the mounting frame 222 to the adhesive layer 224. In some examples, the surface treatment includes an oxygen plasma treatment, another applicable treatment, or a combination thereof. However, in other examples, no surface treatment is performed on the mounting frame 222.

In the embodiment of FIG. 3, a protective layer 240 is applied to the outer surface of the pellicle membrane 230. In certain embodiments, the protective layer 240 is applied by physical vapor deposition (PVD), chemical vapor deposition (CVD), plasma-enhanced CVD, atomic layer deposition (ALD), plasma-enhanced ALD, e-beam evaporation, electroless deposition, electrodeposition, or ion beam deposition (IBD). In certain embodiments, it is desired that the protective layer 240 conforms to the exposed surfaces of the pellicle membrane 230 so that the pores that are present in the pellicle membrane 230 remain present and are not filled by the protective layer 240. Thus, in some embodiments, the pellicle membrane 230 is a porous film or porous membrane. In some embodiments, when applied, the protective layer 240 protects the pellicle membrane 230 from damage that can occur due to heat and hydrogen plasma created during EUV exposure. There is a synergistic effect when a protective layer 240 is applied to pellicle membrane 230 with respect to resisting hydrogen damage.

In some embodiments, the material used for the protective layer 240 has a low refractive index, i.e., as close to 1 as possible when measured at a wavelength of 13.5 nm. In some embodiments, the material used for the protective layer 240 has a low extinction coefficient at a wavelength of 13.5 nm. The extinction coefficient measures how easily the material can be penetrated by the wavelength. In certain embodiments, the material used for the protective layer 240 has a transmittance (T %), when measured at an EUV wavelength of 13.5 nm, greater than 90%, greater than 92%, greater than 94%, or greater than 95%, when measured at a thickness of between 0.5 nanometer and 10 nanometers. This reduces EUV absorption by the protective layer 240 (permitting further downstream processing) while protecting the pellicle membrane 230.

In some embodiments, the material of the protective layer 240 is selected from SiOₓ, SiNₓ, SiCₓ, and oxynitrides or oxycarbides thereof. In other embodiments, the material of the protective layer 240 includes a metal, metal oxide, metal carbide, metal nitride, or metal oxynitride, wherein the metal is selected from one or more of Ru, Nb, Al, or Mo. In other embodiments, the material of the protective layer 240 is selected from one or more of B, BN, B₄C, B₂O₃, B₆Si, SiN, Si₃N₄, SiN₂, SiC, SiZr, SiCₓN_{y}, Nb, NbN, NbSi, NbSiN, Nb₂O₅, NbTiₓN_{y}, NbC, Nb₅Si₃, ZrNₓ, ZrYₓO_{y}, ZrF, ZrF₄, ZrSi₂, YN, Y₂O₃, YF, Mo, MO₂N, MoSi, MoSi₂, MoSiN, MoC₂, MoC, MoS₂, MoN, Ru, RuNb, RuSiN, RuO₂, TiN, TiCₓN_{y}, HfO₂, HfNₓ, HfF₄, VN, Rh, Pt, Pd, W, Cr, Ni, Fe, Co, Ag, Au, Zr, Y, or a composite thereof. In some embodiments, the protective layer 240 has a thickness of about 0.5 nanometers (nm) to about 10 nm. In some embodiments, the thickness of the protective layer 240 is between about 1 nm and about 8 nm.

In certain embodiments, when one or more additional elements selected from Si, B, C, N, and P are present in the BCN nanostructures, a mixing interface (not shown) occurs between the pellicle membrane 230 and the protective layer 240. The mixing interface in some embodiments is between about 1 nm to about 5 nm. The mixing interface provides additional exposure stability. In some embodiments, the protective layer 240 is in the form of a continuous film, nano-grains, nano-particles, nano-sheets, or combinations thereof. In some embodiments, the coating is made of multiple layers of the materials listed above, each layer having any of the forms listed above.

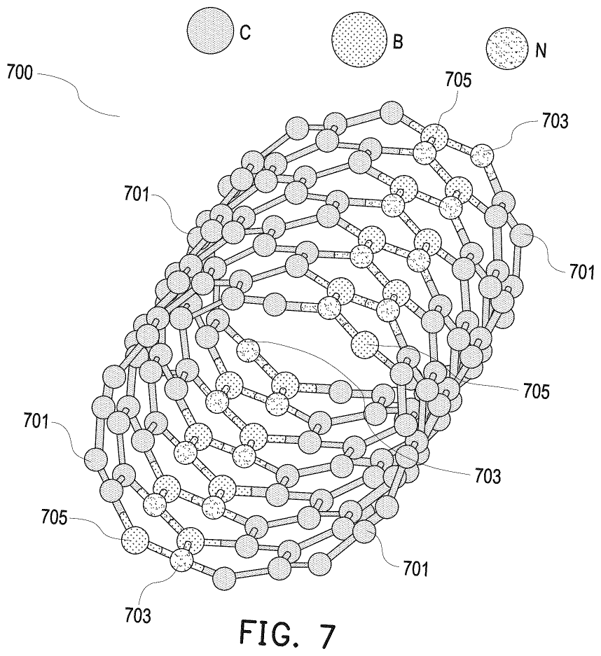

As shown in FIG. 7, an example of a BCN nanostructure 700 is shown. The BCN nanostructure 700 is shown as a nanotube structure including cylindrical molecules that include rolled-up sheets of single-layer carbon atoms 701, nitrogen atoms 703, and boron atoms 705.

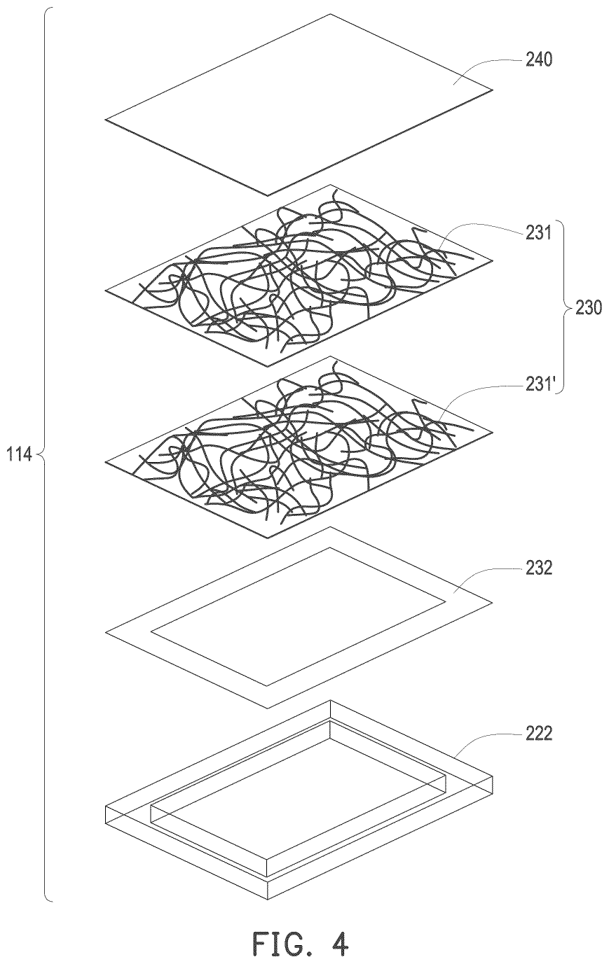

FIG. 4 is an exploded view of a pellicle 114 in accordance with some embodiments of the present disclosure. In certain embodiments, the pellicle membrane 230 is a single or multi-layer membrane formed from a network of BCN nanostructures. In some embodiments, an atomic percentage of carbon in the BCN nanostructures is optimized to increase strength of the BCN nanostructures. In some examples, the BCN nanostructure includes an atomic percentage of carbon ranging from about 1.2 to 3.6. Examples of BCN nanostructures include BC_{1.2}N, BC_{1.9}N_{1.1}, BC_{2.4}N_{1.3}, BC_{2.8}N_{1.4}, and BC_{3.6}N_{1.7}.

In the embodiment of FIG. 4, the pellicle membrane 230 includes a first layer of BCN nanostructures 231 and a second layer of BCN nanostructures 231'. The two layers 231 and 231′ of the pellicle membrane 230 contact each other via van der Waals forces, and the BCN nanostructures in each layer 231 and 231′ do not become entangled with the other layer. In some embodiments, a protective layer 240 is applied to the outer surface of the pellicle membrane 230. In other embodiments, the protective layer 240 is applied to an inner surface(s) of the pellicle membrane 230. In the embodiment of FIG. 4, the protective layer 240 and the pellicle membrane 230 are enclosed within a border frame 232. In certain embodiments, the border frame 232 is fixed to the mounting frame 222 by way of an adhesive layer 224 (FIG. 3). The pellicle 114 is then fixedly mounted on the photomask 108. In certain embodiments, the pellicle 114 is fixedly secured to the photomask 108 with an adhesive or the like.

In some embodiments of the present disclosure, the use of BCN nanostructures in the pellicle membrane 230 provides a membrane that exhibits mechanical and optical properties that deliver effective or advantageous performance during the use of the pellicle membrane in EUV lithography. Other useful physical properties include resistance to high temperature, the ability to maintain a flat non-wrinkled form during preparation and use of the pellicle, and resistance to reactive chemicals (especially resistance to degradation by hydrogen radicals).

In certain embodiments, a pellicle membrane 230 as described, by containing BCN nanostructures, is made to be both very thin and lightweight. In some embodiments, the pellicle membrane 230 is a thin membrane containing a network of BCN nanostructures. In some embodiments, the BCN nanostructures include a network of nanotubes, nanowires, nanofibers, nanosheets, or nanocages dispersed within the pellicle membrane 230, and connected or interconnected to form a thin but cohesive membrane. In certain embodiments, the BCN nanostructures include various molecular and structural arrangements of BCN. In certain embodiments, the BCN nanostructures include a morphology arranged in a periodic nanocrystalline form, an amorphous form, or a polycrystalline form.

In certain embodiments, the network of BCN nanostructures making up the pellicle membrane 230 has a structure density sufficient to maximize EUV radiation transmission while minimizing the passage of particles through the pellicle membrane 230. For instance, although a looser structure density may allow for greater EUV radiation transmission, the looser structure density may also allow particles to fall through to the photomask 108. In certain embodiments, the pellicle membrane 230 comprising the BCN nanostructures is formed by a roll-to-roll process, another suitable process, or any combination thereof.

In some embodiments, the pellicle membrane 230 is a single-layer structure. In other embodiments, the pellicle membrane 230 is a multi-layer structure (FIG. 4). In some embodiments, the layers of the multi-layer structure can be made of the same materials, and in other embodiments, the layers of the multi-layer structure can be made of different materials selected for particular purposes and arranged in order as desired. For example, in some embodiments, the pellicle membrane may comprise one or more layers of the BCN nanostructures and one or more layers of carbon nanotubes (CNTs). In some embodiments, the pellicle membrane 230 has a thickness between about 5 nm to about 15 nm. In other embodiments, the pellicle membrane 230 has a thickness of about 10 nm to about 12 nm. In certain embodiments, the pellicle membrane comprises BCN, BC₂N, BC₃N, BC₄N, BC₅N, or BC₆N nanostructures.

In certain embodiments of the present disclosure, the BCN nanostructures are in the form of nanotubes, nanowires, nanofibers, nanosheets, or nanocages. In certain embodiments, an initial nanostructure membrane is formed from nanotube bundles. In some embodiments, this is performed by arranging the nanotube bundles next to each other. Without being bound by any one particular theory, it is believed that the nanotube bundles are held together by van der Waals forces of sufficient strength to form the initial nanotube membrane. In certain embodiments, the initial nanotube membrane is annealed at temperatures of about 1000° C. to about 2000° C. In certain embodiments, the initial nanotube membrane is treated to reduce its thickness and obtain the pellicle membrane 230. In certain embodiments, the initial nanotube membrane undergoes compression or immersion in a solution to obtain the desired thickness.

In some embodiments, the network of BCN nanostructures is formed using several different fabrication processes. For example, fabrication processes such as chemical vapor deposition (CVD), floating catalyst CVD, plasma-enhanced CVD, electrophoretic deposition; dispersal in a solution and concentration by removal of the solvent, vacuum filtration, and the like. In some embodiments, the BCN nanotubes are formed by directly spinning nanotubes from a floating catalyst CVD system. The direct spinning process begins by providing a reactor vessel. In some examples, the reactor vessel is equipped with a heat source to ensure a specified temperature in the reactor vessel. In certain embodiments, the BCN nanotubes are then grown in the vessel and form an aerogel that is then capable of being spun into a fiber.

In certain embodiments, the pellicle membrane 230 has a Young's modulus between about 1.18 TPa and about 1.33 TPa; a maximum tensile strength between about 30 GPa to about 100 GPa; thermal conductivity of about 3,000 W/m K to about 4,000 W/m K; and is stable up to a temperature of about 800° C. in air.

In some embodiments, the nanostructures of the pellicle membrane 230 are randomly oriented or are directionally oriented in a desired direction. In some embodiments, the nanostructures of the pellicle membrane 230 are all randomly oriented. In some embodiments, the nanostructures of the pellicle membrane 230 are all directionally oriented. In these embodiments, the directionally oriented nanostructures are aligned at an angle (e.g., 0 to 180 degrees) relative to each other.

In certain embodiments, the network of BCN nanostructures includes one or more dopants. In some embodiments, the dopant concentration in the network of BCN nanostructures is from about 0 to about 15 atomic % (at. %). In other embodiments, the dopant concentration in the network of BCN nanostructures is between about 7 at. % to about 10 at. %. Dopant concentrations above 15 at. % can decrease transmission of the pellicle membrane and reduce the mechanical strength of the pellicle membrane. In certain embodiments, the BCN nanostructures are doped with one or more dopants selected from Mo, O, Nb, Si, or Y. In some embodiments, the dopant material is selected from one or more of silicon nitride (SiN), molybdenum disilicide (MoSi₂), molybdenum silicide (Mo₅Si₃), and Mo₃Si (molybdenum trisilicide). In certain embodiments, the dopant acts as a grain growth controller that assists in exposure stability. In some embodiments, the dopant concentration in BCN nanostructures enhances the exposure durability of the pellicle membrane 230. In other embodiments an additional element is included in the BCN nanostructure and selected from Si, B, C, N, P, or O, and alloys or mixtures thereof to optimize optical and mechanical properties. In yet other embodiments, a low extinction coefficient (low-K) material is included in the nanostructure for exposure stability. In some embodiments, the low-K material has an extinction coefficient of about 0.01 to 0 and adjustable by film composition and intrinsic optical constant. Examples of low-K material include a material containing one or more of Mo, Nb, Zr, Y, Ca, S, P, K, Sr, Rb, Si, and Cl. In certain embodiments, the low-K material is fabricated from a precursor, target or reactive synthesis by process including, but not limited to PVD, CVD, ALD, and ion beam.

In certain embodiments, the BCN nanostructures undergo thermal and mechanical stress during EUV lithography. The thermal and mechanical stress can alter the grain growth of the nanostructures and can lead to coarsening of gains which may reduce the material strength and hardness of the BCN nanostructures. Moreover, cracking can occur in the BCN nanostructures which is initiated by grain boundary migration, stress concentration, and the presence of defects. The high surface energy and the presence of grain boundaries in BCN nanostructures can make them more susceptible to cracking. In certain embodiments of the present disclosure, the dopant concentration controls the grain size in BCN nanostructures and helps reduce the occurrence of cracking in the BCN nanostructures. In other embodiments, the dopant is provided at grain boundaries of the BCN nanostructures to suppress oxidation and reduce the loss of nitrogen or carbon atoms at the grain boundaries of the BCN nanostructures.

In certain embodiments of the present disclosure, the dopant concentration is controlled and penetration of the dopant material into the BCN nanostructures of the pellicle membrane 230 is limited. In some embodiments, an intermixing between the dopant material and the BCN nanostructures occurs. In certain examples, the dopant material penetrates to a depth of about 0 to about 3 nm into the grains of the BCN nanostructures.

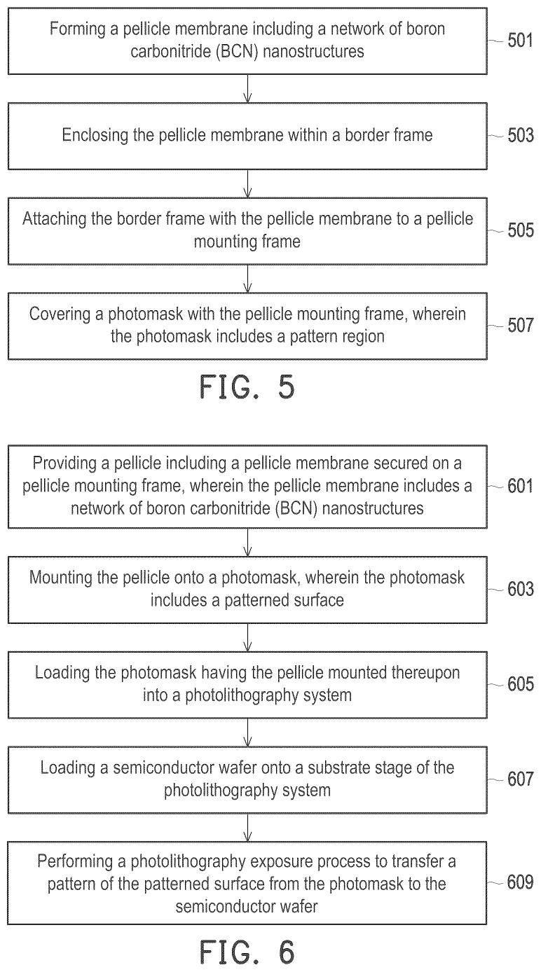

FIG. 5 is a flowchart for a method of forming a photomask-pellicle assembly 205. The method includes step 501 of forming a pellicle membrane 230 including a network of BCN nanostructures 501. The method includes step 503 of enclosing the pellicle membrane 230 within a border frame 232. The method includes the step 505 of attaching the border frame 232 with the pellicle membrane 230 to a pellicle mounting frame 222. The method also includes the step 507 of covering a photomask 108 with the pellicle mounting frame 222, wherein the photomask 108 includes a pattern region 210.

FIG. 6 is a flowchart for a method of manufacturing a semiconductor device. The method includes step 601 of providing a pellicle 114 including a pellicle membrane 230 secured on a pellicle mounting frame 222. The pellicle membrane includes a network of BCN nanostructures. The method includes the step 603 of mounting the pellicle 114 onto a photomask 108, wherein the photomask 108 includes a patterned surface 210. The method includes the step 605 of loading the photomask 108 having the pellicle 114 mounted thereupon into a photolithography system 100. The method includes the step 607 of loading a semiconductor wafer 116 onto a substrate stage 112 of the photolithography system 100. The method includes the step 609 of performing a photolithography exposure process to transfer a pattern of the patterned surface from the photomask 108 to the semiconductor wafer 116.

Thus, examples of the present disclosure provide a robust, high transmission BCN nanostructure pellicle that is resistant to temperature- and pressure-induced deformation and that transmits a high percentage (e.g., greater than 94%) of radiation onto the photomask. The pellicle of the present disclosure may be especially suitable for use in ultraviolet lithography systems, and more particularly in EUV lithography systems.

In one example, the present disclosure provides a method of forming a photomask-pellicle assembly. The method includes forming a pellicle membrane including a network of boron carbonitride (BCN) nanostructures. The method includes enclosing the pellicle membrane within a border frame. The method includes attaching the border frame with the pellicle membrane to a pellicle mounting frame. The method includes covering a photomask with the pellicle mounting frame, wherein the photomask includes a pattern region.

In certain embodiments, the network of BCN nanostructures includes nanotubes, nanowires, nanofibers, nanosheets, or nanocages. In some embodiments, the network of BCN nanostructures comprises one or more dopants selected from molybdenum (Mo), oxygen (O), niobium (Nb), silicon (Si), or yttrium (Y). In some embodiments, a concentration of the one or more dopants is 15 atomic percent (at. %) or less. In some embodiments, the concentration of the one or more dopants is 7 at. % to 10 at. %. In other embodiments, a thickness of the pellicle membrane is 5 nanometers (nm) to 15 nm. In certain embodiments, the method includes forming a protective layer over the pellicle membrane. In some embodiments, the protective layer comprises one or more selected from a metal, metal oxide, metal carbide, metal nitride, or metal oxynitride. In some embodiments, a thickness of the protective layer is 0.5 nm to 10 nm. In other embodiments, the photomask includes a substrate, alternating reflective layers, spacing layers, and a capping layer.

In another example, a method of manufacturing a semiconductor device is provided. The method includes providing a pellicle including a pellicle membrane secured on a pellicle mounting frame. The pellicle membrane includes a network of boron carbonitride (BCN) nanostructures. The method includes mounting the pellicle onto a photomask, wherein the photomask includes a patterned surface. The method includes loading the photomask having the pellicle mounted thereupon into a photolithography system. The method includes loading a semiconductor wafer onto a substrate stage of the photolithography system. The method includes performing a photolithography exposure process to transfer a pattern of the patterned surface from the photomask to the semiconductor wafer.

In certain embodiments, the photolithography exposure process generates light selected from deep ultraviolet (DUV) light or extreme ultraviolet (EUV) light. In some embodiments, the network of BCN nanostructures includes one or more dopants selected from molybdenum (Mo), oxygen (O), niobium (Nb), silicon (Si), or yttrium (Y). In some embodiments, a concentration of the one or more dopants is 15 atomic percent (at. %) or less. In other embodiments, a protective layer is formed over the pellicle membrane. In some embodiments, the protective layer is selected from one or more of SiOₓ, SiNₓ, SiCₓ, and oxynitrides or oxycarbides thereof.

In another example, a pellicle for semiconductor photolithography is provided. The pellicle includes a pellicle membrane including at least one porous film. The at least one porous film includes a network of boron carbonitride (BCN) nanostructures. A border frame is attached to the pellicle membrane along a peripheral region of the pellicle membrane. A mounting frame is attached to the border frame.

In some embodiments, a protective layer is disposed over the pellicle membrane. In some embodiments, the network of BCN nanostructures includes one or more dopants selected from molybdenum (Mo), oxygen (O), niobium (Nb), silicon (Si), or yttrium (Y). In other embodiments, a concentration of the one or more dopants is 15 atomic percent (at. %) or less.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of forming a photomask-pellicle assembly, comprising:
forming a pellicle membrane including a network of boron carbonitride (BCN) nanostructures;
enclosing the pellicle membrane within a border frame;
attaching the border frame with the pellicle membrane to a pellicle mounting frame; and
covering a photomask with the pellicle mounting frame, wherein the photomask includes a pattern region.

2. The method of claim 1, wherein the network of BCN nanostructures includes nanotubes, nanowires, nanofibers, nanosheets, or nanocages.

3. The method of claim 1, wherein the network of BCN nanostructures comprises one or more dopants selected from molybdenum (Mo), oxygen (O), niobium (Nb), silicon (Si), or yttrium (Y).

4. The method of claim 3, wherein a concentration of the one or more dopants is 15 atomic percent (at. %) or less.

5. The method of claim 4, wherein the concentration of the one or more dopants is 7 at. % to 10 at. %.

6. The method of claim 1, wherein the network of BCN nanostructures further comprises one or more of Si, B, C, N, P, and O, and alloys thereof.

7. The method of claim 1, further comprising:
forming a protective layer over the pellicle membrane.

8. The method of claim 7, wherein the protective layer comprises one or more selected from a metal, metal oxide, metal carbide, metal nitride, or metal oxynitride.

9. The method of claim 8, wherein the network of BCN nanostructures further comprises a low-K dielectric material.

10. The method of claim 1, wherein the photomask further comprises a substrate, alternating reflective layers, spacing layers, and a capping layer.

11. A method of manufacturing a semiconductor device, comprising:
providing a pellicle including a pellicle membrane secured on a pellicle mounting frame, wherein the pellicle membrane includes a network of boron carbonitride (BCN) nanostructures;
mounting the pellicle onto a photomask, wherein the photomask includes a patterned surface;
loading the photomask having the pellicle mounted thereupon into a photolithography system;
loading a semiconductor wafer onto a substrate stage of the photolithography system; and
performing a photolithography exposure process to transfer a pattern of the patterned surface from the photomask to the semiconductor wafer.

12. The method of claim 11, wherein the photolithography exposure process generates light selected from deep ultraviolet (DUV) light or extreme ultraviolet (EUV) light.

13. The photolithography method of claim 11, wherein the network of BCN nanostructures comprises one or more dopants selected from molybdenum (Mo), oxygen (O), niobium (Nb), silicon (Si), or yttrium (Y).

14. The photolithography method of claim 13, wherein a concentration of the one or more dopants is 15 atomic percent (at. %) or less.

15. The photolithography method of claim 11, wherein a protective layer is formed over the pellicle membrane.

16. The photolithography method of claim 15, wherein the protective layer is selected from one or more of SiOₓ, SiNₓ, SiCₓ, and oxynitrides or oxycarbides thereof.

17. A pellicle for semiconductor photolithography, comprising:
a pellicle membrane including at least one porous film, the at least one porous film including a network of boron carbonitride (BCN) nanostructures;
a border frame attached to the pellicle membrane along a peripheral region of the pellicle membrane; and
a mounting frame attached to the border frame.

18. The pellicle of claim 17, wherein a protective layer is disposed over the pellicle membrane.

19. The pellicle of claim 17, wherein the network of BCN nanostructures includes one or more dopants selected from molybdenum (Mo), oxygen (O), niobium (Nb), silicon (Si), or yttrium (Y).

20. The pellicle of claim 19, wherein a concentration of the one or more dopants is 15 atomic percent (at. %) or less.
